(19) United States
(12) Patent Application Publication
(10) Pub. No.: US 2026/0230077 A1
(43) Pub. Date: Aug. 6, 2026

(54) Low Propagation Delay Voltage Level Translator Circuit

(71) Applicant: Texas Instruments Incorporated, Dallas, TX (US)

(72) Inventors: Sahil Garg, Bangalore (IN); Ajith Kumar Narayanasetty, Bangalore (IN); Tarunvir Singh, Richardson, TX (US); Upasana Bhattacharya, Bangalore (IN); Sreeram Nasum S, Bangalore (IN)

(21) Appl. No.: 19/043,356

(22) Filed: Jan. 31, 2025

(51) Int. Cl. H03K 19/0185; H03K 3/356

(52) U.S. Cl. CPC H03K 19/018521; H03K 3/356113

(57) ABSTRACT

A circuit includes a first transistor coupled to a first power supply terminal and an output terminal of the circuit, and a second transistor coupled to the output terminal and a second power supply terminal. A first plurality of buffers receives the output of a level shifter and has an output coupled to a control terminal of the first transistor, and a second plurality of buffers receives an input of the circuit and has an output coupled to a control terminal of the second transistor. In an example, a boost circuit has an input coupled to an output of one of the second plurality of buffers, and an output coupled to an output of one of the first plurality of buffers. In another example, the level shifter outputs a shifted input signal having a voltage swing between a voltage at the first power supply terminal and a reference voltage.

### BACKGROUND

This specification relates to the design and manufacture of electronic circuits, more particularly voltage level translator circuits.

In the field of electronic circuits, a circuit referred to as a voltage level translator, level shifter, or logic-level shifter is used to translate signals from one logic level or power supply voltage domain to another. In providing this function, voltage level translators allow compatibility and enable communication between circuits that operate under differing voltage specifications. For example, voltage level translators are used in a variety of application environments to bridge voltage domains between processors, logic, sensors, and other circuits such as analog frond end (AFE) circuits and input/output (I/O) drivers.

Continuing trends in the design and manufacture of electronic systems have resulted in more stringent performance requirements for voltage level translators. In the automotive context, for example, power and speed considerations favor lower power supply voltages and logic levels for processor and logic integrated circuits, but many peripheral devices such as sensors and actuators require operation in a higher voltage domain than that of the processor. Voltage level translators are required to interface the processors and peripheral devices operating in these differing voltage domains. However, the high data rates required in modern automotive systems, for example in carrying out serial-parallel interface (SPI) communications, place severe constraints on the propagation delay allowable for voltage level translation.

### SUMMARY

According to an example, a circuit includes a first transistor having a first terminal coupled to a first power supply terminal and a second terminal coupled to an output terminal of the circuit; a second transistor having a first terminal coupled to a second power supply terminal and a second terminal coupled to the output terminal of the circuit; and a level shifter having an input coupled to an input terminal of the circuit and having first and second bias terminals coupled to the first and second power supply terminals, respectively. A first plurality of buffers has an input coupled to the output of the level shifter and an output coupled to the control terminal of the first transistor. Each of the first plurality of buffers has first and second bias terminals coupled to the first and second power supply terminals, respectively. A second plurality of buffers has an input coupled to the input terminal of the circuit and an output coupled to the control terminal of the second transistor. Each of the second plurality of buffers has a first and second bias terminals coupled to a third power supply terminal and the second power supply terminal, respectively. The circuit further includes a boost circuit having an input coupled to an output of one of the second plurality of inverters, and an output coupled to an output of one of the first plurality of inverters.

According to another example, a circuit includes a first transistor having a first terminal coupled to a first power supply terminal and a second terminal coupled to an output terminal of the circuit, and a second transistor having a terminal coupled to a second power supply terminal and a second terminal coupled to the output terminal of the circuit. A level shifter has an input coupled to an input terminal of the circuit, first and second bias terminals coupled to the first and second power supply terminals, respectively, and a third bias terminal coupled to a reference voltage terminal. A first plurality of buffers has an input coupled to the output of the level shifter and an output coupled to the control terminal of the first transistor. Each of the first plurality of buffers has first and second bias terminals coupled to the first power supply terminal and the reference voltage terminal, respectively. A second plurality of buffers has an input coupled to the input terminal of the circuit and an output coupled to the control terminal of the second transistor. Each of the second plurality of buffers has first and second bias terminals coupled to a third power supply terminal and the second power supply terminal, respectively.

According to another example, a voltage level translator includes an input buffer having an input coupled to an input terminal, and digital logic having an input coupled to an output of the input buffer via a data path, and having first and second bias terminals coupled to first and second power supply terminals, respectively. A level shifter has an input coupled to the output of the digital logic, first and second bias terminals coupled to the first and power supply terminals, respectively, and a third bias terminal coupled to a third power supply terminal. The voltage level translator further includes an output buffer circuit including a first transistor having a first terminal coupled to a first power supply terminal and a second terminal coupled to an output terminal of the circuit; a second transistor having a first terminal coupled to a second power supply terminal and a second terminal coupled to the output terminal of the circuit; and a level shifter having an input coupled to an input terminal of the circuit, and first and second bias terminals coupled to the first and second power supply terminals, respectively. A first plurality of buffers has an input coupled to the output of the level shifter and an output coupled to the control terminal of the first transistor. Each of the first plurality of buffers has first and second bias terminals coupled to the first and second power supply terminals, respectively. A second plurality of buffers has an input coupled to the input terminal of the circuit and an output coupled to the control terminal of the second transistor. Each of the second plurality of buffers has first and second bias terminals coupled to a third power supply terminal and the second power supply terminal, respectively. The output buffer further includes a boost circuit having an input coupled to an output of one of the second plurality of inverters, and an output coupled to an output of one of the first plurality of inverters.

According to another example, a circuit includes a level shifter having an input coupled to an input terminal of the circuit. A first plurality of buffers has an input coupled to the output of the level shifter and an output coupled to the control terminal of a first transistor. Each of the first plurality of buffers has first and second bias terminals coupled to a first power supply terminal and a reference voltage terminal, respectively. A second plurality of buffers has an input coupled to the input terminal of the circuit and an output coupled to the control terminal of a second transistor. Each of the second plurality of buffers has first and second bias terminals coupled to a third power supply terminal and the second power supply terminal, respectively. The first transistor has a terminal coupled to a first power supply terminal and a second terminal coupled to an output terminal of the circuit, and the second transistor has a terminal coupled to a second power supply terminal and a second terminal coupled to the output terminal of the circuit. The level shifter is configured to output a shifted signal responsive to an input signal received at the input terminal, where the received input signal has a voltage swing between a voltage at the third power supply terminal and a voltage at the second power supply terminal and the shifted signal has a voltage swing between a voltage at the first the first power supply terminal and a voltage at the reference voltage terminal. The voltage at the first power supply terminal is higher than the voltage at the third power supply terminal.

Example technical advantages enabled by one or more of these examples include improved propagation delay in the output buffers of voltage level translator circuits. The improved propagation delay can be obtained in applications utilizing low power supply voltages for processor and control logic.

Other example technical advantages enabled by this disclosure are apparent to those of ordinary skill in the art having reference to the following specification together with its drawings.

### BRIEF DESCRIPTION OF THE DRAWINGS

FIG. 1 is an electrical diagram, in block form, of an example system.

FIG. 2 is an electrical diagram, in block form, of an example voltage level translator in the system of FIG. 1.

FIG. 3 is an electrical diagram, in block and schematic form, of a prior art output buffer in a voltage level translator.

FIG. 4 is an electrical diagram, in block and schematic form, of an example level shifter and output buffer for the system of FIG. 1.

FIG. 5 is an electrical diagram, in block and schematic form, illustrating an example boost circuit in the output buffer of FIG. 4.

FIG. 6 is a timing diagram, from simulation, illustrating propagation delay in the example output buffer of FIGS. 4 and 5 relative to that of a prior art output buffer.

FIG. 7 is an electrical diagram, in block and schematic form, of another example level shifter and output buffer for the system of FIG. 1.

FIG. 8A is an electrical diagram, in schematic form, of an example level shifter for the example of FIG. 7.

FIG. 8B is a timing diagram, from simulation, illustrating propagation delay at certain nodes in the example level shifter of FIG. 7.

The same reference numbers or other reference designators are used in the drawings to illustrate the same or similar (in function and/or structure) features.

### DETAILED DESCRIPTION

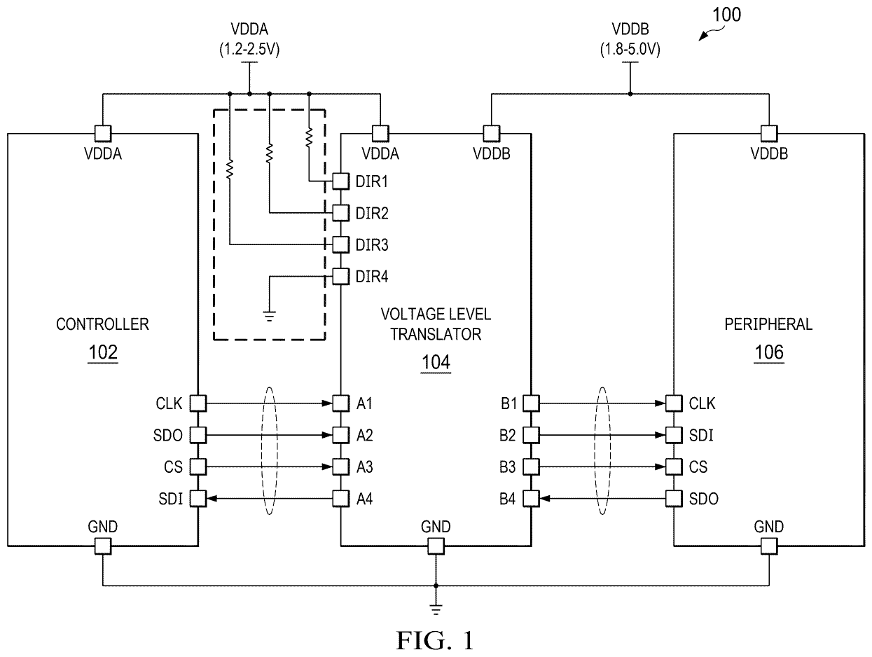

FIG. 1 depicts an example system 100 in which described examples are implemented. System 100 includes controller 102, voltage level translator 104, and peripheral device 106. Controller 102 may be implemented in the form of a microprocessor, microcomputer, or other control logic. Peripheral device 106 may be a sensor, a controller such as a motor controller, device actuator, and the like, or alternatively may be another instance of control or operational circuitry.

In example system 100, controller 102 has power supply terminal VDDA and power supply terminal GND, output terminals CLK, SDO, and CS, and input terminal CDI. For example, controller 102 may output a system clock signal from terminal CLK, serial output data signals from terminal SDO, and a chip select signal from terminal CS, and receive serial input data signals at terminal SDI. Peripheral device 106 has power supply terminal VDDB, power supply terminal GND, input terminals CLK, SDI, and CS, and output terminal SDO. Peripheral device 106 may receive a system clock signal at its terminal CS, serial input data signals at its terminal SDI, and a chip select signal at its terminal CS, and output serial output data signals at its terminal SDO.

In system operation, the power supply voltage applied to power supply terminal VDDA of controller 102 differs from that applied to power supply terminal VDDB of peripheral device 106. Power supply terminals GND of both controller 102 and peripheral device receive a common potential (e.g., system or circuit ground) in this example. These differing power supply voltages at terminals VDDA and VDDB relative to the voltage at terminals GND define separate voltage “domains” in which system 100 operates. In this example, the power supply voltage at terminal VDDA (e.g., at a voltage between 1.2V and 2.5V) is lower than the power supply voltage at terminal VDDB (e.g., at a voltage between 1.8V and 5.0V).

The relatively low voltage bias of controller 102, between the power supply voltage at terminal VDDA and ground, enables controller 102 to be implemented with low voltage metal-oxide-semiconductor (MOS) transistors, and thus operate with low power consumption and at fast switching speeds. On the other hand, peripheral device 106 in example system 100 requires a higher voltage at its power supply terminal VDDB to carry out its function. For example, sensors, controllers, and actuators in many automotive systems require higher power supply voltages than do high speed logic circuitry. The difference between the voltage “domains” of controller 102 and peripheral device 106 in example system 100 of FIG. 1 is also reflected in a difference in the voltage “swing” of logic signals communicated between controller 102 and peripheral device 106. For example, the logic levels of signals output from terminals CLK, SDO, and CS of controller 102 have a relatively low voltage swing (e.g., between the power supply voltage at terminal VDDA and ground) as compared with the logic levels required of input signals to terminals CLK, SDI, and CS of peripheral device 106 (e.g., between the power supply voltage at terminal VDDB and ground).

For purposes of this description, the voltage domain defined by the voltages applied to power supply terminals VDDA and GND is referred to herein as “the VDDA voltage domain,” and the voltage domain defined by the voltages applied to power supply terminals VDDB and GND is referred to herein as “the VDDB voltage domain.” In system 100 of FIG. 1, controller 102 is biased in the VDDA voltage domain, and the signals input to and output from controller 102 have a signal swing corresponding to the VDDA voltage domain. Conversely, peripheral device 106 is biased in the VDDB voltage domain, and the signals input to and output from peripheral device 106 have a signal swing corresponding to the VDDB voltage domain.

Voltage level translator 104 is a bidirectional voltage level translator device provided to translate the logic levels of signals from the VDDA voltage domain of controller 102 to the VDDB voltage domain of peripheral device 106, and vice versa for signals communicated from peripheral device 106 to controller 102. Voltage level translator 104 has a power supply terminal VDDA, power supply terminal VDDB, and power supply terminal GND. In example system 100, power supply terminal VDDA of voltage level translator 104 receives the same power supply voltage as terminal VDDA of controller 102, power supply terminal VDDB of voltage level translator 104 receives the same power supply voltage as terminal VDDB of controller 106, and power supply terminal GND is coupled to circuit ground.

Voltage level translator 104 has signal terminals A1, A2, A3, and A4, which are coupled to terminals CLK, SDO, CS, and SDI of controller 102, respectively. Signals at signal terminals A1 through A4 are in the VDDA voltage domain. Voltage level translator 104 has signal terminals B1, B2, B3, and B4, which are coupled to terminals CLK, SDI, CS, and SDO of peripheral device 106, respectively. Signals at terminals B1 through B4 are in the VDDB voltage domain. Voltage level translator 104 is constructed to communicate signals in either direction between its terminals A1 and B1, A2 and B2, A3 and B3, and A4 and B4, supporting four signal channels in this example.

Voltage level translator 104 also has terminals DIR1, DIR2, DIR3, and DIR4, which select the direction of signal communication of its corresponding signal channel in response to an applied voltage. In this example, terminal DIR1 is coupled (e.g., through a resistor) to the power supply voltage at terminal VDDA, configuring voltage level translator 104 to drive output signals at terminal B1 in response to input signals received at terminal A1. Similarly, terminals DIR2, DIR3 are each coupled (e.g., through a resistor) to the power supply voltage at terminal VDDA, configuring voltage level translator 104 to drive output signals at terminals B2 and B3 in response to input signals received at terminals A2 and A3, respectively. Terminal DIR4 is coupled to circuit ground, which configures voltage level translator 104 to drive output signals at terminal A4 in response to input signals received at terminal B4.

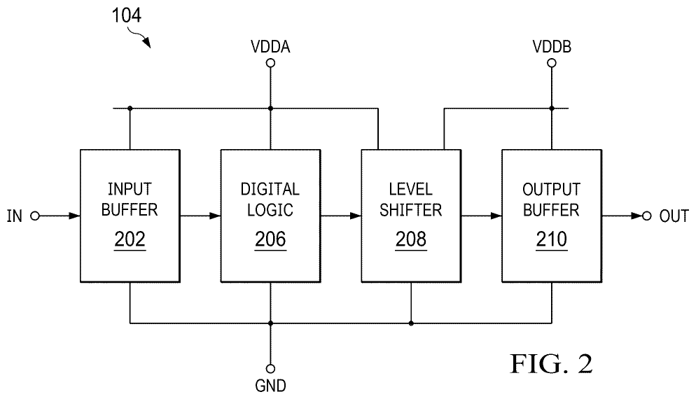

FIG. 2 illustrates an example functional architecture of one signal channel of voltage level translator 104 for communicating signals from the VDDA voltage domain to the VDDB voltage domain. This architecture may correspond to any of the four signal channels of example voltage level translator 104 of FIG. 1. Voltage level translator 104 as shown in FIG. 2 includes input buffer 202, digital logic 206, level shifter 208, and output buffer 210.

Input buffer 202 has an input coupled to input terminal IN, which corresponds to the one of terminals A1 through A4 for that channel. An output of input buffer 202 is coupled to an input of digital logic 206. Digital logic 206 may include relatively simple logic circuitry (e.g., one or more logic gates), for example. Digital logic 206 can enable and disable the appropriate buffers and drivers according to the selected direction (e.g., in response to a voltage at the corresponding terminal DIR1 through DIR4) and any enable signals (not shown) received by voltage level translator 104. An output of digital logic 206 is coupled to an input of level shifter 208, which has an output coupled to an input of output buffer 210. Output buffer 210 has an output coupled to output terminal OUT, namely the one of terminals B1 through B4 corresponding to the particular device terminal at input terminal IN.

In this example, input terminal IN represents one of terminals A1 through A4 of voltage level translator 104, and output terminal OUT represents the corresponding one of terminals B1 through B4. Accordingly, input buffer 202 and digital logic 206 each have a bias terminal coupled to power supply terminal VDDA of voltage level translator 104 and another bias terminal coupled to power supply terminal GND, and are thus biased in the VDDA voltage domain. Output buffer 210 has a bias terminal coupled to power supply terminal VDDB of voltage level translator 104, and another bias terminal coupled to power supply terminal GND, and is thus biased in the VDDB voltage domain.

Level shifter 208 has a bias terminal coupled to power supply terminal VDDA, a bias terminal coupled to power supply terminal VDDB, and a bias terminal coupled to power supply terminal GND. As described below, level shifter 208 operates to shift the logic levels of signals communicated through voltage level translator 104 from one voltage domain (e.g., the VDDA voltage domain) to another voltage domain (e.g., the VDDB voltage domain).

The architecture of a channel of voltage level translator 104 for translating signals from the VDDB voltage domain to the VDDA voltage domain is similar to that shown in FIG. 1, but with input buffer 202 and digital logic 206 having bias terminals coupled to power supply terminal VDDB and output buffer 210 having bias terminals coupled to power supply terminal VDDA. For this direction, terminal IN corresponds to one of terminals B1 through B4 of voltage level translator 104, and output terminal OUT represents the corresponding one of terminals A1 through A4.

As described relative to FIG. 1, voltage level translator 104 translates signals between the different voltage domains biasing controller 102 and peripheral device 106. This translation necessarily involves some propagation delay, however. The performance of certain high speed applications, such as a serial-parallel interface (SPI) between controller 102 and peripheral device 106, as now common in many system applications such as in the automotive context, may be limited by the propagation delay of voltage level translator 104. For the example of SPI communication, which requires the transmitting device to receive acknowledgement of a transmitted signal within the same clock period as its transmission, the propagation delay of voltage level translator 104 may limit the clock frequency and thus the clock rate of the SPI communications. For example, an SPI clock rate of 100 Mbps (megabits per second) requires the propagation delay of voltage level translator 104 to be less than 10 nsec.

The bulk of the propagation delay in voltage level translators according to the prior art has been observed to lie in the output buffer. For example, the observed propagation delays of each component of one example of a prior art voltage level translator, biased from a power supply voltage of 1.8V±10% and for the case of signal translation from a lower voltage domain to a higher voltage domain, are:

TABLE 1

| Component | Propagation delay | |
|---|---|---|
| Input buffer | 3.5 | nsec |
| Data path | 1.5 | nsec |
| Digital logic | 1.5 | nsec |
| Level shifter | 3 | nsec |
| Output buffer | 10 | nsec |
| Total | ~20 | nsec |

The component of “Data path” in Table 1 refers to the propagation delay of conductors and terminations in the signal path among the components of the voltage level translator. The maximum SPI clock rate attainable for this example is thus limited to 50 Mbps, with the output buffer being the primary limiting factor.

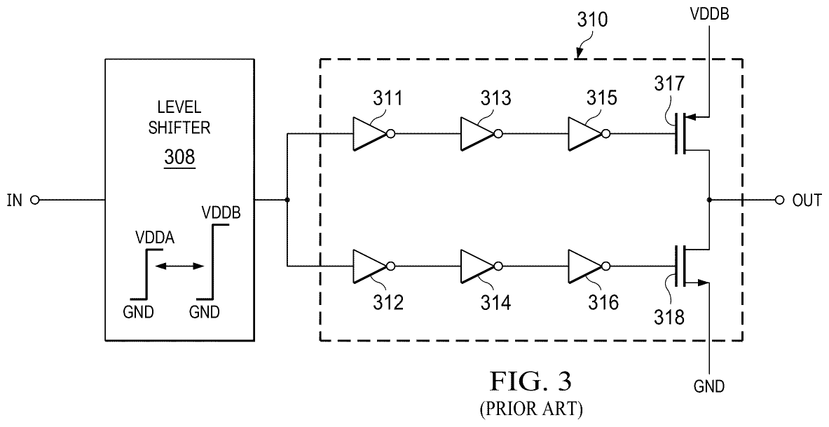

FIG. 3 illustrates an example voltage level translator output buffer 310 according to the prior art, in combination with a level shifter 308 as implemented into a voltage level translator. More specifically, output buffer 310 of FIG. 3 is implemented as part of a signal channel for communications in the direction from a lower voltage domain to a higher voltage domain. Output buffer 310 includes inverters 311, 312, 313, 314, 315, 316, p-channel MOS (PMOS) transistor 317, and n-channel MOS (NMOS) transistor 318.

Level shifter 308 in this prior art example operates to shift the “1” logic level of a received input signal from about the voltage at power supply terminal VDDA (e.g., which may be as low as 1.5V) to about the voltage at power supply terminal VDDB (e.g., nominally 5V, but which may be as high as 5.5 V). The “0” logic level of the signals both received and output by level shifter 308 is at circuit ground.

In an upper branch of output buffer 310, inverter 311 has an input coupled to the output of level shifter 308, and an output coupled to an input of inverter 313. Inverter 315 has an input coupled to an output of inverter 313, and an output coupled to the gate of PMOS transistor 317. PMOS transistor 317 has its source coupled to power supply terminal VDDB, and its drain coupled to output terminal OUT. In a lower branch of output buffer 310, inverter 312 has an input coupled to the output of level shifter 308, and an output coupled to an input of inverter 314. Inverter 316 has an input coupled to an output of inverter 314, and an output coupled to the gate of NMOS transistor 318. PMOS transistor 317 has its source coupled to ground, and its drain coupled to output terminal OUT. In this prior art example, each of inverters 311, 312, 313, 314, 315, 316 is biased between the voltage at power supply terminal VDDB and ground.

As mentioned above, the power supply voltage applied to power supply terminal VDDB may be as high as 5.5 V (e.g., 5.0 V±10%). Accordingly, each of PMOS transistor 317 and NMOS transistor 308 is constructed as a “high-voltage” transistor capable of withstanding at least a 5.5V drain-to-source voltage. Inverters 311 through 316 must be similarly constructed to support a 5.5V bias voltage. However, the actual power supply voltage applied to terminal VDDB may be less than this maximum level, in which case the drive strength of inverters 311 through 316, PMOS transistor 317, and NMOS transistor 318 is poor. This reduced drive strength leads to slower switching times, and thus a high propagation delay for output buffer 310 specifically, and for the voltage level translator in general.

It is within this context that the examples described herein arise.

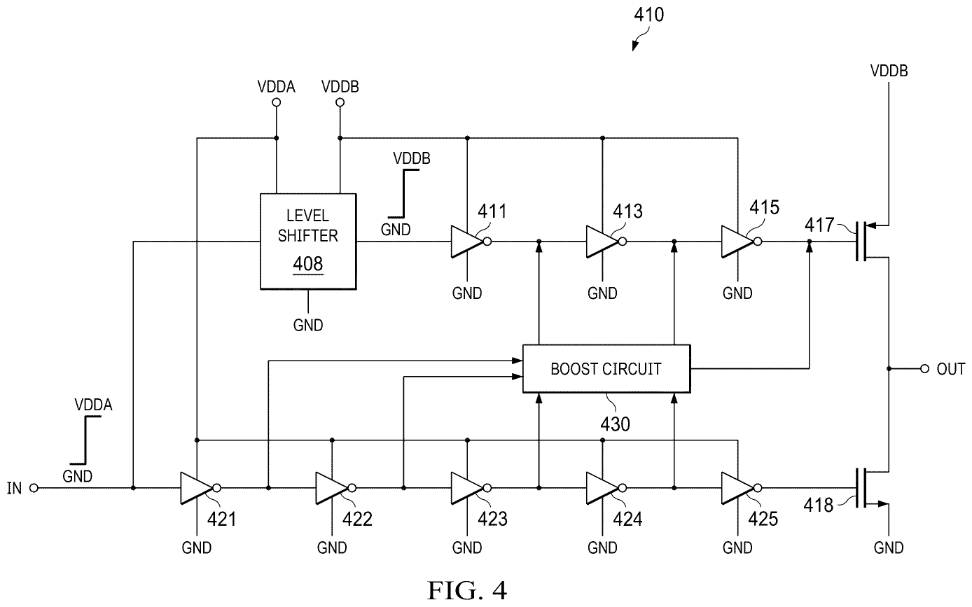

FIG. 4 shows example output buffer 410, in combination with level shifter 408, as may be implemented in voltage level translator 104 of system 100. More specifically, output buffer 410 of FIG. 4 is implemented as part of a signal channel for communications in the direction from a lower voltage domain to a higher voltage domain, for example from the VDDA voltage domain of controller 102 to the VDDB voltage domain of peripheral device 106 in system 100 (FIG. 1). Output buffer 410 in this example includes buffers 411, 413, 415, 421, 422, 423, 424, and 425, transistors 417 and 418, and boost circuit 430.

Level shifter 408 has a bias terminal coupled to power supply terminal VDDA, a bias terminal coupled to power supply terminal VDDB, and a bias terminal coupled to terminal GND (e.g., shown as circuit ground in FIG. 4). Level shifter 408 also has an input coupled to input terminal IN (e.g., to an output of digital logic 202 in FIG. 2), and an output. Level shifter 408 operates to shift the “1” logic level of a signal received at input terminal IN from about the voltage at power supply terminal VDDA (e.g., which may be as low as 1.5V) to about the voltage at power supply terminal VDDB (e.g., which may be as high as 5.5 V in this example). The “0” logic level of the signals both received and output by level shifter 408 is at or near circuit ground. Accordingly, level shifter 408 shifts the input signal from the VDDA voltage domain to the VDDB voltage domain (e.g., from a signal swing of 0-1.5V to a signal swing of 0-5V).

In the upper branch of output buffer 410, buffer 411 has an input coupled to the output of level shifter 408. Buffer 413 has an input coupled to an output of buffer 411, and buffer 415 has an input coupled to an output of buffer 413. In this example, each of buffers 411, 413, 415 is implemented as an inverter, and each has a bias terminal coupled to power supply terminal VDDB and a bias terminal coupled to terminal GND (e.g., shown as circuit ground in FIG. 4).

Transistor 417 has a terminal coupled to power supply terminal VDDB, a terminal coupled to output terminal OUT, and a control terminal coupled to an output of buffer 415. In example output buffer 410 of FIG. 4, transistor 417 is implemented as a PMOS transistor with a source coupled to power supply terminal VDDB, a drain coupled to output terminal OUT, and a gate coupled to the output of inverter 415.

The multiple inverters 411, 413, 415 in upper branch of output buffer 410 in this example are constructed with transistors of increasing size, and thus with increasing drive strength. In an example, inverter 413 has twice the drive strength as inverter 411, and inverter 415 has twice the drive strength as inverter 413. This increase in drive strength provides adequate gate drive for the relatively large transistor 417 driving the output signal to peripheral device 106 in system 100.

In the lower branch of output buffer 410, buffer 421 has an input coupled to input terminal IN. Buffer 422 has an input coupled to an output of buffer 421, buffer 423 has an input coupled to the output of buffer 422, buffer 424 has an input coupled to the output of buffer 423, and buffer 425 has an input coupled to the output of buffer 424. In example output buffer 410, each of buffers 421, 422, 423, 424, 425 is an inverter (and will be referred to below as such), and has a bias terminal coupled to power supply terminal VDDA and a bias terminal coupled to ground. For this case in which the voltage at power supply terminal VDDA is lower than that at power supply terminal VDDB, inverters 421, 422, 423, 424, 425 may be implemented using low voltage transistors. For example, inverters 421, 422, 423, 424, 425 may be implemented as 1.5V inverters of increasing drive strength (e.g., implemented with transistors of increasing size). This construction of inverters 421, 422, 423, 424, 425 provides for fast switching times in response to the reduced voltage swing (e.g., between 1.5V and ground) of the input signals received at terminal IN.

Transistor 418 has a terminal coupled to output terminal OUT, a terminal coupled to terminal GND (e.g., shown as circuit ground in the example of FIG. 4), and a control terminal coupled to an output of inverter 425. In this example, transistor 418 is implemented as an NMOS transistor with a source coupled to ground, a drain coupled to output terminal OUT, and a gate coupled to the output of inverter 425.

Output buffer 410 in this example includes boost circuit 430. Boost circuit 430 has one or more inputs coupled to the output of one or more of inverters 421, 422, 423, 424, 425 in the lower branch of output buffer 410, and one or more outputs coupled to the output of one or more of inverters 411, 412, 413 in the upper branch. Boost circuit 430 is provided to improve the switching speed at the outputs of upper branch inverters 411, 413, 415, which are implemented as higher-voltage (e.g., 5V) devices and thus have slower switching speed than the lower voltage devices of inverters 421, 422, 423, 424, 425 in the lower branch.

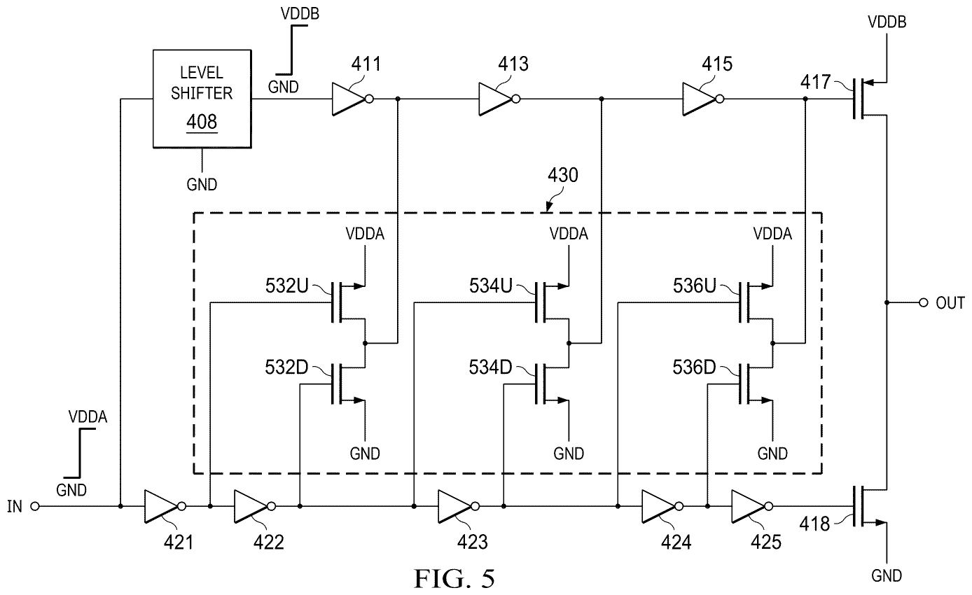

FIG. 5 illustrates the construction of an example boost circuit 430, as implemented in example output buffer 410 of FIG. 4 in combination with level shifter 408. Output buffer 410 includes buffers 411, 413, 415, 421, 422, 423, 424, and 425, transistors 417 and 418, coupled in the manner described above in connection with FIG. 4. Output buffer 410 also includes boost circuit 430, which includes transistors 532U, 532D, 534U, 534D, 536U, 536D.

Transistors 532U, 534U, 536U each have a terminal coupled to power supply terminal VDDA, and have a terminal coupled to the output of inverters 411, 413, 415, respectively, and a control terminal coupled to the output of inverters 421, 422, 423, respectively. Transistors 532D, 534D, 536D have a terminal coupled to the output of inverters 411, 413, 415, respectively, a terminal coupled to power supply terminal GND (e.g., at circuit ground), and a control terminal coupled to the output of inverters 422, 423, 424, respectively. In this arrangement, transistors 532U and 532D form one push-pull circuit. Transistors 534U and 534D form another push-pull circuit, and transistors 536U and 536D form a third push-pull circuit. A push-pull circuit is thus provided at the output of each of inverters 411, 413, 415 in this example.

More particularly, in the example of FIG. 5, transistors 532U, 534U, 536U, 532D, 534D, and 536D are constructed as DENMOS transistors. These transistors may be relatively small devices, for example suitable for 1.8V drain-to-source voltages, and thus have relatively fast switching speeds. Transistor 532U has a source coupled to power supply terminal VDDA, a drain coupled to the output of inverter 411, and a gate coupled to the output of inverter 421. Transistor 534U has a source coupled to power supply terminal VDDA, a drain coupled to the output of inverter 413, and a gate coupled to the output of inverter 422. Transistor 536U has a source coupled to power supply terminal VDDA, a drain coupled to the output of inverter 415, and a gate coupled to the output of inverter 423. Transistor 532D has a source coupled to power supply terminal GND, a drain coupled to the output of inverter 411, and a gate coupled to the output of inverter 422. Transistor 534D has a source coupled to power supply terminal GND, a drain coupled to the output of inverter 413, and a gate coupled to the output of inverter 423. Transistor 536U has a source coupled to power supply terminal GND, a drain coupled to the output of inverter 415, and a gate coupled to the output of inverter 424.

In operation, each of inverters 421, 422, 423, 424, 425 has input and output signal swings in the VDDA voltage domain (e.g., from 0-1.5V), and each of inverters 411, 413, 415 has input and output signal swings in the VDDB voltage domain (e.g., from 0-5V). Boost circuit 430 operates to assist, and thus speed up, switching at the outputs of inverters 411, 413, 415 in order to reduce the signal propagation delay of output buffer 410.

For the case of a logic “1” signal at terminal IN, a logic “1” level will be present at the input of inverters 411 (via level shifter 408) and 421. Inverter 421 will drive a “0” logic level at its output, causing inverter 422 to drive a “1” logic level at its output. In this case, transistor 532U is turned off and transistor 532D is turned on, pulling the output of inverter 411 toward ground. While inverter 411 is itself also driving its output to a “0” logic level in response to the “1” at its input, this transition of inverter 411 is slower than that of inverters 421, 422, due to its construction from higher-voltage (e.g., 5V) devices than those of inverters 421, 422. Transistor 532D thus speeds up the response of inverter 411.

Continuing for this case of a logic “1” input signal, the logic “1” level at the output of inverter 422 causes inverter 423 to drive a “0” level at its output. The “1” level at the output of inverter 422 turns on transistor 534U, and the “0” level at the output of inverter 423 turns off transistor 534D. Meanwhile, the logic “0” level at the output of inverter 411 causes inverter 413 to drive a “1” level at its output. This transition of inverter 413 is assisted by transistor 534U, speeding up its switching and thus the driving of a “1” level at the input of inverter 415.

The logic “0” level at the output of inverter 423 also turns off transistor 536U, and causes inverter 424 to drive a “1” level at its output, turning on transistor 536D. Meanwhile, the “1” level at the output of inverter 413 causes inverter 415 to drive a “0” level at its output, assisted by the action of transistor 536D. This “0” level is applied to the gate of DEPMOS transistor 417, turning it on and driving output terminal OUT toward the power supply voltage at terminal VDDB (e.g., 5V). Meanwhile, inverter 425 drives a “0” level at its output in response to the “1” level output by inverter 424, holding DENMOS transistor 418 off.

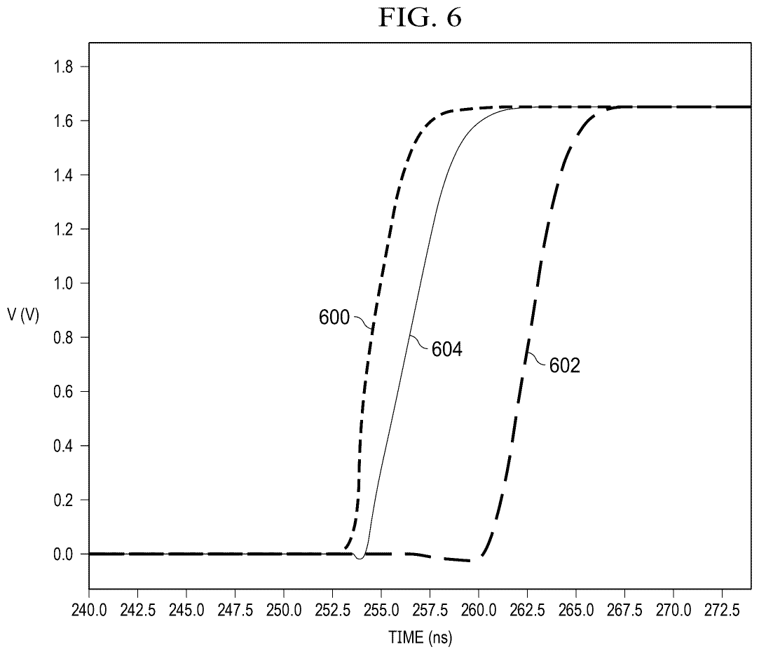

FIG. 6 illustrates a simulation result of the operation of boost circuit 430 in output buffer 410, as compared with a similar circuit without boost circuit 430. Plot 600 in FIG. 6 corresponds to a “0” to “1” transition of an input signal at terminal IN. Plot 602 illustrates the simulated response to this input transition at the output of an output buffer without boost circuit 430, exhibiting a propagation delay of about 8.25 nsec. Plot 604 illustrates the simulated response to this input transition at terminal OUT of output buffer 430 including boost circuit 430, as shown in FIG. 5. Boost circuit 430 in this example reduces the propagation delay of output buffer 410 to about 1.75 nsec. As discussed above, this reduction in propagation delay enables a corresponding increase in the maximum clock rate of communications between controller 102 and peripheral device 106.

Boost circuit 430 will operate in a similar manner for the opposite data state of a “0” level signal at input terminal IN. In that case, transistors 532U, 534D, and 536U are turned on, and transistors 532D, 534U, and 536D turned off, to assist the transitions at the outputs of inverters 411, 413, 415, respectively. A similar improvement in propagation delay as shown in FIG. 6 results for this data state as well.

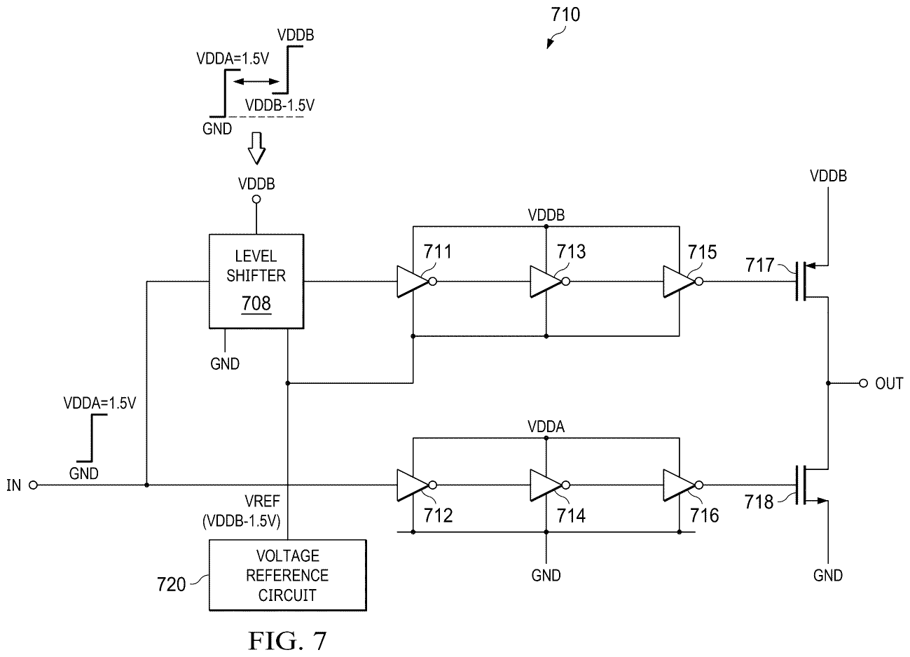

FIG. 7 illustrates another example output buffer 710, in combination with an example level shifter 708, as may be incorporated into voltage level translator 104 in system 100 of FIG. 1. Output buffer 710 includes buffers 711, 712, 713, 714, 715, 716, and transistors 717 and 718. Voltage reference circuit 720 is shown in combination with level shifter 708 and output buffer 710 in the example of FIG. 7.

Level shifter 708 in this example has an input coupled to input terminal IN, which receives an input signal in the VDDA voltage domain. Level shifter 708 has a bias terminal coupled to power supply terminal VDDB, a bias terminal coupled to power supply terminal GND, and a bias terminal coupled to an output terminal VREF of voltage reference circuit. Voltage reference circuit 720 is a bandgap reference or other type of voltage regulator generating a regulated voltage at an output terminal VREF. In this example, voltage reference circuit 720 produces a voltage at output terminal VREF of about 1.5V below the voltage at power supply terminal VDDB.

Level shifter 708 operates to shift the “0” logic level of a signal received at input terminal IN from about the voltage at power supply terminal GND (e.g., circuit ground), to about the voltage at output terminal VREF of voltage reference circuit 720 (e.g., about 1.5V below the voltage at power supply terminal VDDB). Level shifter 708 also operates to shift the “1” logic level of a signal received at input terminal IN from about the voltage at power supply terminal VDDA to about the voltage at power supply terminal VDDB. Accordingly, level shifter 708 maintains the same signal swing of the received input signal in the VDDA voltage domain, but shifts the DC level of that signal swing into the VDDB voltage domain (e.g., from a signal swing of 0-1.5V to a signal swing of 3.5V-5V).

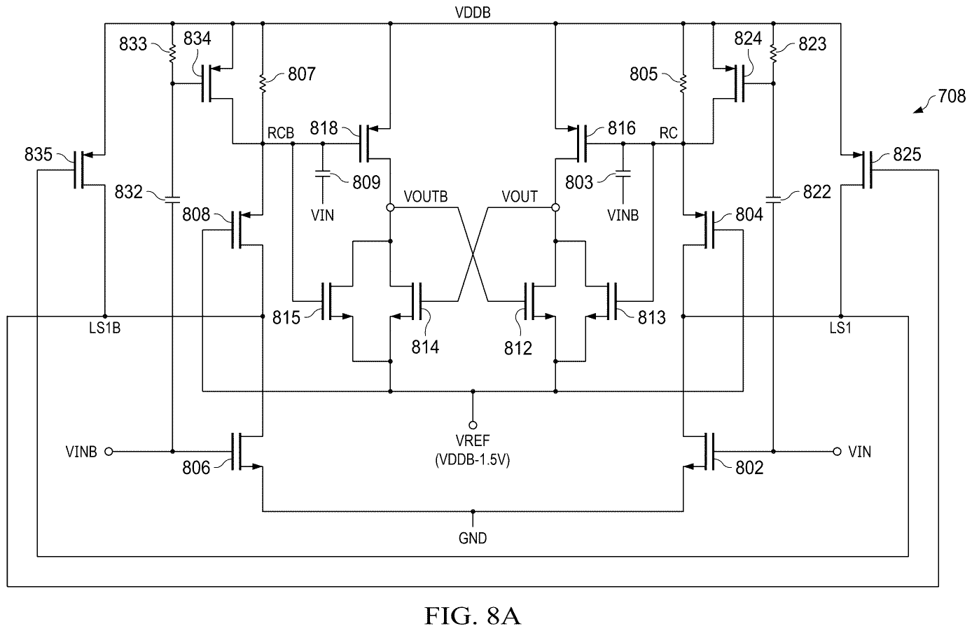

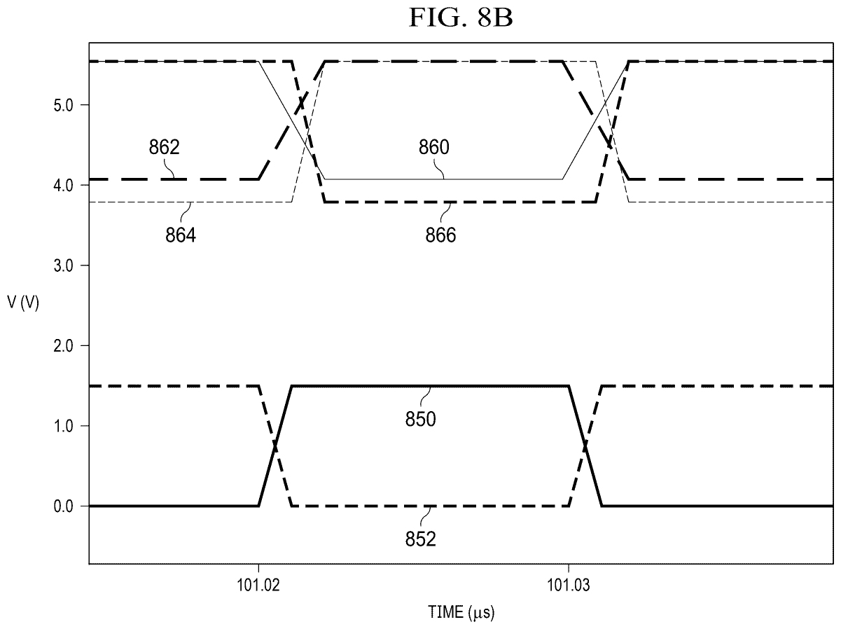

FIG. 8A illustrates the construction of level shifter 708 according to an example. Level shifter 708 includes NMOS transistors 802, 806, 812, 813, 814, and 815; PMOS transistors 804, 808, 816, 818, 824, 825, 834, and 835; capacitors 803, 809, 822, and 832; and resistors 805, 807, 823, and 833.

In this example, the input signal in the VDDA voltage domain received by level shifter 708 is in the form of a differential signal at complementary logic levels, for example as may be generated in input buffer 202 (FIG. 2) in response to the received signal. Accordingly, level shifter 708 of FIG. 8A has complementary input terminals VIN and VINB.

NMOS transistor 802 has a gate coupled to input terminal VIN and a source coupled to terminal GND. PMOS transistor 804 has a drain coupled to a drain of NMOS transistor 802 at node LS1, and a gate coupled to terminal VREF at the output of voltage reference circuit 720. Resistor 805 has one terminal coupled to power supply terminal VDDB and another terminal coupled to a source of PMOS transistor 804 at node RC. Capacitor 803 has one terminal coupled to the source of PMOS transistor 804 at node RC, and another terminal coupled to input terminal VINB. PMOS transistor 816 has a source coupled to power supply terminal VDDB, a gate coupled to node RC, and a drain coupled to an output terminal VOUT of level shifter 708. NMOS transistor 813 has a drain coupled to output terminal VOUT, a source coupled to terminal VREF, and a gate coupled to node RC. NMOS transistor 812 has a drain coupled to output terminal VOUT, a source coupled to terminal VREF, and a gate coupled to complementary output terminal VOUTB. PMOS transistor 824 has a source coupled to power supply terminal VDDB, and a drain coupled to node RC. Resistor 823 has one terminal coupled to power supply terminal VDDB, and another terminal coupled to a gate of PMOS transistor 824. Capacitor 822 has one terminal coupled to a terminal of resistor 823 and the gate of PMOS transistor 824, and another terminal coupled to input terminal VIN. PMOS transistor 825 has a source coupled to power supply terminal VDDB, a drain coupled to node LS1, and a gate.

NMOS transistor 806 has a gate coupled to input terminal VINB and a source coupled to terminal GND. PMOS transistor 808 has a drain coupled to a drain of NMOS transistor 806 and the gate of PMOS transistor 825 at node LS1B, and a gate coupled to terminal VREF at the output of voltage reference circuit 720. Resistor 807 has one terminal coupled to power supply terminal VDDB and another terminal coupled to a source of PMOS transistor 808 at node RCB. Capacitor 809 has one terminal coupled to the source of PMOS transistor 808 at node RCB, and another terminal coupled to input terminal VIN. PMOS transistor 818 has a source coupled to power supply terminal VDDB, a gate coupled to node RCB, and a drain coupled to complementary output terminal VOUTB of level shifter 708. NMOS transistor 815 has a drain coupled to output terminal VOUTB, a source coupled to terminal VREF, and a gate coupled to node RCB. NMOS transistor 814 has a drain coupled to output terminal VOUTB, a source coupled to terminal VREF, and a gate coupled to complementary output terminal VOUT. PMOS transistor 834 has a source coupled to power supply terminal VDDB, and a drain coupled to node RCB. Resistor 833 has one terminal coupled to power supply terminal VDDB, and another terminal coupled to a gate of PMOS transistor 834. Capacitor 832 has one terminal coupled to a terminal of resistor 833 and the gate of PMOS transistor 834, and another terminal coupled to input terminal VINB. PMOS transistor 835 has a source coupled to power supply terminal VDDB, a drain coupled to node LS1B, and a gate coupled to node LS1.

In operation, for example in response to a “0”-to-“1” logic level transition at input terminal VIN and the complementary “1”-to-“0” transition at input terminal VINB, both occurring in the VDDA voltage domain (e.g., with a signal swing between 0V and 1.5V), NMOS transistor 802 turns on and NMOS transistor 806 turns off. PMOS transistor 804 is effectively biased as a current source (e.g., with its gate about 1.5V below the voltage at power supply terminal VDDB), which allows NMOS transistor 802 to pull node RC at the gate of PMOS transistor 816 toward circuit ground. Meanwhile, capacitor 803 also receives the “1”-to-“0” transition at input terminal VINB, which rapidly pulls down the voltage of node RC and thus rapidly turns on PMOS transistor 816. Output terminal VOUT is driven to the voltage at power supply terminal VDDB by PMOS transistor 816, which turns on NMOS transistor 814, pulling output terminal VOUTB to the voltage at terminal VREF (e.g., at the voltage at VDDB—1.5V). This pulling down of output terminal VOUTB is assisted by capacitor 809, which receives the “0”-to-“1” logic level transition at input terminal VIN, boosting the voltage of node RCB at the gate of PMOS transistor and ensuring that PMOS transistor 818 is turned off.

As a result, the “0”-to-“1” logic level transition at input terminal VIN in the VDDA voltage domain is converted to a “0”-to-“1” logic level transition at output terminal VOUT and a complementary “1”-to-“0” transition at output terminal VOUTB. Consider an example in which the voltage at power supply terminal VDDA is 1.5V, the voltage at power supply terminal VDDB is 5V, and the voltage at terminal VREF is the VDDB voltage minus 1.5V, or 3.5V. In that example, a transition at input terminal VIN from 0V to 1.5V results in a transition at output terminal VOUT from 3.5V to 5V, and in a transition at output terminal VOUTB from 5V to 3.5V. Accordingly, in that example, both the signal swing of the input signal and also that of the output signal are about 1.5V. However, level shifter 708 shifts the DC level of the output signal to have about a 1.5V signal swing between the voltage at power supply voltage VDDB and the voltage at terminal VREF.

This “inner” loop of level shifter 708 may be implemented with low voltage high-performance transistors to attain a low propagation delay. More particularly, NMOS transistors 812, 813, 814, and 818, and PMOS transistors 816, 818, 824, and 834 in level shifter 708 are implemented as 1.8V high performance MOS transistors. NMOS transistors 802 and 806, and PMOS transistors 804 and 808 in this example are implemented as higher voltage (e.g., 5V) DEMOS devices in order to tolerate source-to-drain voltages as high as the voltage at terminal VDDB.

Level shifter 708 of FIG. 8A according to this example also includes an “outer” loop to further assist switching of the output latch formed by cross-coupled NMOS transistors 812, 813, 814, and 818, and PMOS transistors 816 and 818. In operation, again for example in response to “0”-to-“1” and “1”-to-“0” logic level transitions at input terminals VIN and VINB, respectively, the turning on of NMOS transistor 802 pulls node LS1 toward circuit ground, which turns on PMOS transistor 835. This on-state of transistor 835 actively pulls node LS1B toward the voltage at terminal VDDB, more quickly than through the action of PMOS transistor 808 alone with NMOS transistor 806 off. The high voltage at node LS1B due to on-state PMOS transistor 835 turns off PMOS transistor 825, which allows its drain, at node LS1, to be pulled toward circuit ground by on-state NMOS transistor 802. PMOS transistors 825 and 835 may be implemented as high voltage devices, to withstand drain-to-source voltages as high as the voltage at terminal VDDB (e.g., 5V).

The response at nodes RC and RCB and output terminal VOUT to a transition of a “0”-to-“1” logic level transition at input terminal VIN and the complementary “1”-to-“0” transition at input terminal VINB is shown in the timing diagram of FIG. 8B, by way of simulation. Plot 850 shows the voltage at input terminal VIN and plot 852 the voltage at input terminal VINB, each of which have signal swings of about 1.5V. Plot 860 shows the voltage at node RC, plot 862 shows the voltage at node RCB, plot 864 shows the voltage at output terminal VOUT, and plot 866 shows the voltage at output terminal VOUTB.

At about time 101.02 μsec in FIG. 8B, the signals at input terminals VIN, VINB start their transitions. For this case of a “0”-to-“1” logic level transition at input terminal VIN, NMOS transistor 802 turns on in response as input terminal VIN goes high, pulling node RC at the gate of PMOS transistor 816 toward circuit ground as shown by plot 860. Meanwhile, the action of capacitor 832 in response to the “1”-to-“0” transition at terminal VINB and the action of capacitor 809 in response to the “0”-to-“1” transition at terminal VIN rapidly boost node RCB toward the voltage at terminal VDDB (e.g., toward 5V in FIG. 8B), as shown by plot 862. The increasing voltage at node RCB turns on transistor 815 and the decreasing voltage at node RC turns on PMOS transistor 816, setting the state of the cross-coupled latch of level shifter 708, and driving output terminals VOUT and VOUTB to high and low logic levels respectively, as shown by their respective plots 864 and 866. The response of level shifter 708 is extremely rapid, due to the action of its inner and outer loops, resulting in a propagation delay of on the order of 1 nsec in this simulation.

Operation of level shifter 708 for the opposite transition of a “0”-to-“1” logic level transition at input terminal VIN and the complementary “1”-to-“0” transition at input terminal VINB corresponds to that described above, but with those transistors turned on that were turned off in the previous case, and vice versa. FIG. 8B illustrates a simulation at nodes VIN, VINB, RC, RCB, VOUT, VOUTB for this opposite transition, commencing at about time 101.03. As evident from that portion of FIG. 8B, complementary nodes in level shifter 708 behave in the same manner for this opposite transition. FIG. 8B illustrates a simulation of the response of level shifter 708 to this complementary transition, beginning at about 101.03 μsec.

Accordingly, as described above, level shifter 708 operates to shift the input signal at terminal IN from the VDDA voltage domain to the VDDB voltage domain, but maintaining the same signal swing (e.g., 1.5V). In other words, level shifter 708 produces a signal in the VDDB voltage domain that has the small (e.g., 1.5V) signal swing of the VDDA voltage domain. In this example, level shifter 708 with its inner and outer loops, as described above, can rapidly execute this level shifting operation within the context of output buffer 710.

As shown in FIG. 7, the output of level shifter 708 is coupled to an input of buffer 711, which has an output coupled to an input of buffer 713. Buffer 713 in turn has an output coupled to an input of buffer 715, which has an output coupled to a gate of PMOS transistor 717. PMOS transistor 717 has a source coupled to power supply terminal VDDB, and a drain coupled to output terminal OUT. In this example, each of buffers 711, 713, 715 is implemented as an inverter, and each has a bias terminal coupled to power supply terminal VDDB and a bias terminal coupled to the output VREF voltage reference circuit 720 (e.g., at the voltage at terminal VDDB minus 1.5V). The multiple inverters 711, 713, 715 in this upper branch of output buffer 710 in this example are constructed with transistors of increasing size, and thus with increasing drive strength. In an example, inverter 713 has twice the drive strength as inverter 711, and inverter 715 has twice the drive strength as inverter 713, to provide adequate gate drive for the relatively large transistor 717. However, because of the small signal swing output by level shifter 708, and the reduced bias across inverters 711, 713, 715 (e.g., about 1.5V between the voltages at terminals VDDB and VREF), inverters 711, 713, 715 can be constructed using low voltage high-performance transistors, with low propagation delay. The small signal swing (e.g., 1.5V) at the output of inverter 715 is suitable, as the gate voltage of PMOS transistor 717 need only be driven below the voltage at terminal VDDB by a threshold voltage in order to turn on transistor 717.

In the lower branch of output buffer 710, buffer 712 has an input coupled to input terminal IN, buffer 714 has an input coupled to an output of buffer 712, and buffer 716 has an input coupled to the output of buffer 714. An output of buffer 716 is coupled to a gate of NMOS transistor 718, which has a drain coupled to output terminal OUT and a source coupled to terminal GND (e.g., at circuit ground). Again, buffers 712, 714, 716 may be implemented as inverters of increasing size, to provide sufficient gate drive to transistor 718. Inverters 712, 714, 716 each have a bias terminal coupled to power supply terminal VDDA and a bias terminal coupled to the terminal GND, and as such can be constructed using low voltage high-performance transistors to attain low propagation delay.

PMOS transistor 717 and NMOS transistor 718 can be implemented as DEPMOS and DENMOS transistors, respectively, to tolerate high drain-to-source voltage (e.g., as high as the voltage at terminal VDDB, or 5V).

This construction of output buffer 710, including level shifter 708 as described above relative to FIGS. 8A and 8B and low voltage buffers 711 through 716 as described above relative to FIG. 7, can attain very low propagation delay, for example on the order of 1.6 nsec, as opposed to the 10 nsec propagation delay observed in prior art output buffers (FIG. 3). Accordingly, this example of output buffer 710, when implemented into voltage level translator 100 of FIG. 1, enables high clock rate communications, for example in the form of an SPI interface between controller 102 and peripheral device 106.

In addition, the drain-to-source voltage of PMOS transistor 717 is significantly larger than its gate-to-source voltage as applied by inverter 715 when turning on transistor 717 (e.g., V_{DS} of ~5V as compared with V_{GS} Of 1.5V). Similarly, the drain-to-source voltage of NMOS transistor 718 (e.g., V_{DS} of ~5V) is significantly larger than its gate-to-source voltage (e.g., V_{GS} of 1.5V) as applied by inverter 716 when turning on transistor 718. Transistors 717 and 718 are thus in the saturation state for most of the time of signal transition, during which they provide constant drive current over variations in drain voltage. This constant current driven by transistors 717 and 718 in saturation results in improved noise performance of output buffer 710, for example as compared with prior art output buffer 310 of FIG. 3, in which output transistors 317 and 318 operate in the triode region most of the time during signal transition.

Examples are described in this specification as implemented into voltage level translator circuits, as such implementation can be advantageous in that context. However, aspects of these examples may be beneficially applied in alternative applications in which voltage level translation or conversion is necessary. Accordingly, the above description is provided by way of example only, and is not intended to limit the true scope as claimed.

As used herein, the terms “terminal”, “node”, “interconnection” and “pin” are used interchangeably. Unless specifically stated to the contrary, these terms are generally used to mean an interconnection between or a terminus of a device element, a circuit element, an integrated circuit, a device, or other electronics or semiconductor component.

Unless otherwise stated, “about,” “approximately,” or “substantially” preceding a value means +/−10 percent of the stated value. Modifications are possible in the described examples, and other examples are possible within the scope of the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. While, in some example embodiments, certain elements are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications are possible in the described examples, and other examples are possible, within the scope of the claims.

What is claimed is:

1. A circuit, comprising:
a first transistor having a first terminal coupled to a first power supply terminal, a second terminal coupled to an output terminal of the circuit, and a control terminal;
a second transistor having a first terminal coupled to a second power supply terminal, a second terminal coupled to the output terminal of the circuit, and a control terminal;
a level shifter having an input coupled to an input terminal of the circuit, and having an output;
a first plurality of buffers having an input coupled to the output of the level shifter and an output coupled to the control terminal of the first transistor, each of the first plurality of buffers having a first bias terminal coupled to the first power supply terminal and a second bias terminal coupled to the second power supply terminal;
a second plurality of buffers having an input coupled to the input terminal of the circuit and an output coupled to the control terminal of the second transistor, each of the second plurality of buffers having a first bias terminal coupled to a third power supply terminal and a second bias terminal coupled to the second power supply terminal; and
a boost circuit, having an input coupled to an output of one of the second plurality of inverters, and having an output coupled to an output of one of the first plurality of inverters.

2. The circuit of claim 1, wherein the first plurality of buffers comprises a first plurality of inverters, and the second plurality of buffers comprises a second plurality of inverters;
and wherein the boost circuit comprises:
a third transistor having a first terminal coupled to the third power supply terminal, a second terminal coupled to the output of a first one of the first plurality of inverters, and a control terminal coupled to the output of a first one of the second plurality of inverters; and
a fourth transistor having a first terminal coupled to the second power supply terminal, a second terminal coupled to the output of the first one of the first plurality of inverters, and a control terminal coupled to the output of a second one of the second plurality of inverters.

3. The circuit of claim 2, wherein the boost circuit further comprises:
a fifth transistor having a first terminal coupled to the third power supply terminal, a second terminal coupled to the output of a second one of the first plurality of inverters, and a control terminal coupled to the output of the second one of the second plurality of inverters; and
a sixth transistor having a first terminal coupled to the second power supply terminal, a second terminal coupled to the output of the second one of the first plurality of inverters, and a control terminal coupled to the output of a third one of the second plurality of inverters.

4. The circuit of claim 3, wherein the third, fourth, fifth, and sixth transistors are drain-extended n-channel metal-oxide-semiconductor (DENMOS) transistors.

5. The circuit of claim 1, wherein the first and second pluralities of buffers each comprise an odd number of inverters;
wherein the first transistor is a metal-oxide-semiconductor (MOS) transistor of a first conductivity type;
and wherein the second transistor is a MOS transistor of a second conductivity type.

6. A circuit, comprising:
a first transistor having a first terminal coupled to a first power supply terminal, a second terminal coupled to an output terminal of the circuit, and a control terminal;
a second transistor having a first terminal coupled to a second power supply terminal, a second terminal coupled to the output terminal of the circuit, and a control terminal;
a level shifter having an input coupled to an input terminal of the circuit, an output, a first bias terminal coupled to the first power supply terminal, a second bias terminal coupled to the second power supply terminal, and a third bias terminal coupled to a reference voltage terminal;
a first plurality of buffers having an input coupled to the output of the level shifter and an output coupled to the control terminal of the first transistor, each of the first plurality of buffers having a first bias terminal coupled to the first power supply terminal and a second bias terminal coupled to the reference voltage terminal; and
a second plurality of buffers having an input coupled to the input terminal of the circuit and an output coupled to the control terminal of the second transistor, each of the second plurality of buffers having a first bias terminal coupled to a third power supply terminal and a second bias terminal coupled to the second power supply terminal.

7. The circuit of claim 6, wherein a first voltage domain corresponds to a voltage between the first and second power supply terminals;
wherein a second voltage domain corresponds to a voltage between the third and second power supply terminals, the voltage at the third power supply terminal being lower than the voltage at the first power supply terminal;
and wherein the level shifter is configured to translate signals at the input terminal from logic levels in the second voltage domain to logic levels between the voltage at the first power supply terminal and the reference voltage terminal.

8. The circuit of claim 7, wherein the voltage between the first power supply terminal and the reference voltage terminal is substantially the same as the voltage between the third and second power supply terminals.

9. The circuit of claim 6, wherein the first plurality of buffers comprises an odd number of inverters;
wherein the second plurality of buffers comprises an odd number of inverters;
and wherein the first and second transistors are metal-oxide-semiconductor (MOS) transistors of opposite conductivity type from one another.

10. The circuit of claim 6, wherein the level shifter has first and second inputs, and first and second outputs, and comprises:
a third transistor having a first terminal coupled to the second power supply terminal, a second terminal, and a control terminal coupled to the first input;
a fourth transistor having a first terminal, a second terminal coupled to the second terminal of the third transistor, and a control terminal coupled to the reference voltage terminal;
a first resistor, having a first terminal coupled to the first power supply terminal and a second resistor coupled to the first terminal of the fourth transistor;
a fifth transistor, having a first terminal coupled to the reference voltage terminal, a second terminal coupled to the first output, and a control terminal coupled to the first terminal of the fourth transistor;
a sixth transistor, having a first terminal coupled to the first power supply terminal, a second terminal coupled to the first output, and a control terminal coupled to the first terminal of the fourth transistor;
a first capacitor, having a first terminal coupled to the control terminal of the sixth transistor and a second terminal coupled to the second input;
a seventh transistor having a first terminal coupled to the second power supply terminal, a second terminal, and a control terminal coupled to the second input;
an eighth transistor having a first terminal, a second terminal coupled to the second terminal of the seventh transistor, and a control terminal coupled to the reference voltage terminal;
a second resistor, having a first terminal coupled to the first power supply terminal and a second terminal coupled to the first terminal of the eighth transistor;
a ninth transistor, having a first terminal coupled to the reference voltage terminal, a second terminal coupled to the second output, and a control terminal coupled to the first terminal of the eighth transistor;
a tenth transistor, having a first terminal coupled to the first power supply terminal, a second terminal coupled to the second output, and a control terminal coupled to the first terminal of the eighth transistor;
a second capacitor, having a first terminal coupled to the control terminal of the tenth transistor and a second terminal coupled to the first input;
an eleventh transistor, having a first terminal coupled to the reference voltage terminal, a second terminal coupled to the first output, and a control terminal coupled to the second output; and
a twelfth transistor, having a first terminal coupled to the reference voltage terminal, a second terminal coupled to the second output, and a control terminal coupled to the first output.

11. The circuit of claim 10, wherein the level shifter further comprises:
a thirteenth transistor, having a first terminal coupled to the first power supply terminal, a second terminal coupled to the second terminal of the third transistor, and a control terminal coupled to the second terminal of the seventh transistor;
a third capacitor, having a first terminal, and having a second terminal coupled to the first input;
a third resistor, having a first terminal coupled to the first power supply terminal and a second terminal coupled to the first terminal of the third capacitor;
a fourteenth transistor, having a first terminal coupled to the first power supply terminal, a second terminal coupled to the control terminal of the sixth transistor, and a control terminal coupled to the first terminal of the third capacitor;
a fifteenth transistor, having a first terminal coupled to the first power supply terminal, a second terminal coupled to the second terminal of the seventh transistor, and a control terminal coupled to the second terminal of the third transistor;
a fourth capacitor, having a first terminal, and having a second terminal coupled to the second input;
a fourth resistor, having a first terminal coupled to the first power supply terminal and a second terminal coupled to the first terminal of the fourth capacitor; and
a sixteenth transistor, having a first terminal coupled to the first power supply terminal, a second terminal coupled to the control terminal of the tenth transistor, and a control terminal coupled to the first terminal of the fourth capacitor.

12. A voltage level translator, comprising:
an input buffer having an input terminal, and having an output;
digital logic having an input coupled to the output of the input buffer, an output, a first bias terminal coupled to a first power supply terminal, and a second bias terminal coupled to a second power supply terminal;
a level shifter having an input coupled to the output of the digital logic, and having an output; and
an output buffer comprising:
a first transistor having a first terminal coupled to a third power supply terminal, a second terminal coupled to the output terminal, and a control terminal;
a second transistor having a first terminal coupled to the second power supply terminal, a second terminal coupled to the output terminal, and a control terminal;
a first plurality of buffers having an input coupled to the output of the level shifter and an output coupled to the control terminal of the first transistor, each of the first plurality of buffers having a first bias terminal coupled to the third power supply terminal and a second bias terminal coupled to the second power supply terminal; and
a second plurality of buffers having an input coupled to the output of the digital logic and an output coupled to the control terminal of the second transistor, each of the second plurality of buffers having a first bias terminal coupled to the first power supply terminal and a second bias terminal coupled to the second power supply terminal; and
a boost circuit, having a plurality of inputs, each coupled to an output of one of the second plurality of inverters, and having a plurality of outputs, each coupled to an output of one of the first plurality of inverters.

13. The voltage level translator of claim 12, wherein the boost circuit comprises:
a third transistor having a first terminal coupled to the first power supply terminal, a second terminal coupled to the output of a first one of the first plurality of inverters, and a control terminal coupled to the output of a first one of the second plurality of inverters;
a fourth transistor having a first terminal coupled to the second power supply terminal, a second terminal coupled to the output of the first one of the first plurality of inverters, and a control terminal coupled to the output of a second one of the second plurality of inverters;
a fifth transistor having a first terminal coupled to the first power supply terminal, a second terminal coupled to the output of a second one of the first plurality of inverters, and a control terminal coupled to the output of the second one of the second plurality of inverters; and
a sixth transistor having a first terminal coupled to the second power supply terminal, a second terminal coupled to the output of the second one of the first plurality of inverters, and a control terminal coupled to the output of a third one of the second plurality of inverters.

14. The voltage level translator of claim 12, wherein the third, fourth, fifth, and sixth transistors are drain-extended n-channel metal-oxide-semiconductor (DENMOS) transistors.

15. The voltage level translator of claim 12, wherein the first and second pluralities of inverters each comprise an odd number of inverters;
wherein the first transistor is a metal-oxide-semiconductor (MOS) transistor of a first conductivity type;
and wherein the second transistor is a MOS transistor of a second conductivity type.

16. A circuit, comprising:
a level shifter having an input coupled to an input terminal of the circuit, and an output;
a first plurality of buffers having an input coupled to the output of the level shifter, and having an output, each of the first plurality of buffers having a first bias terminal coupled to a first power supply terminal and a second bias terminal coupled to a reference voltage terminal; and
a second plurality of buffers having an input coupled to the input terminal of the circuit, and having an output, each of the second plurality of buffers having a first bias terminal coupled to a second power supply terminal and a second bias terminal coupled to a third power supply terminal;
a first transistor having a first terminal coupled to the first power supply terminal, a second terminal coupled to an output terminal of the circuit, and a control terminal coupled to the output of the first plurality of buffers; and
a second transistor having a first terminal coupled to the third power supply terminal, a second terminal coupled to the output terminal of the circuit, and a control terminal coupled to the output of the second plurality of buffers;
wherein the level shifter is configured to output a shifted signal responsive to an input signal received at the input terminal, the received input signal having a voltage swing between a voltage at the second power supply terminal and a voltage at the third power supply terminal, and the shifted signal having a voltage swing between a voltage at the first power supply terminal and a voltage at the reference voltage terminal;
and wherein the voltage at the first power supply terminal is higher than the voltage at the second power supply terminal.

17. The circuit of claim 16, wherein the voltage swing of the shifted signal is substantially the same as the voltage swing of the received input signal.

18. The circuit of claim 16, wherein the first plurality of buffers comprises an odd number of inverters;
wherein the second plurality of buffers comprises an odd number of inverters;
and wherein the first and second transistors are metal-oxide-semiconductor (MOS) transistors of opposite conductivity type from one another.

19. The circuit of claim 16, wherein the level shifter has first and second inputs, and first and second outputs, and comprises:
a first input transistor having a control terminal coupled to the first input, and having a conduction path;
a first load device having a conduction path coupled in series with the conduction path of the first input transistor between the first power supply terminal and the third power supply terminal;
a second input transistor having a control terminal coupled to the second input, and having a conduction path;
a second load device having a conduction path coupled in series with the conduction path of the second input transistor between the first power supply terminal and the third power supply terminal;
a first output transistor, having a conduction path coupled between the first power supply terminal and the first output, and a control terminal coupled to the first load device;
a first cross-coupled transistor having a conduction path coupled between the first output terminal and the reference terminal, and having a control terminal coupled to the second output;
a second output transistor, having a conduction path coupled between the first power supply terminal and the second output, and a control terminal coupled to the second load device;
a second cross-coupled transistor having a conduction path coupled between the second output and the reference terminal, and having a control terminal coupled to the first output;
a first capacitor, having a first plate coupled to the control terminal of the first output transistor and a second plate coupled to the second input;
a third transistor, having a conduction path coupled between the first output and the reference terminal, and a control terminal coupled to the first plate of the first capacitor;
a second capacitor, having a first plate coupled to the control terminal of the second output transistor and a second plate coupled to the first input; and
a fourth transistor, having a conduction path coupled between the second output and the reference voltage terminal, and a control terminal coupled to the first plate of the second capacitor.

20. The circuit of claim 16, wherein the level shifter further comprises:
a fifth transistor, having a conduction path coupled between the first power supply terminal and a first intermediate output at the conduction paths of the first input transistor and the first load device, and having a control terminal;
a sixth transistor, having a conduction path coupled between the first power supply terminal and a second intermediate output coupled to the conduction paths of the second input transistor and the second load device, and having a control terminal coupled to the first intermediate output, the second intermediate output coupled to the control terminal of the fifth transistor;
a third capacitor, having a first plate, and having a second plate coupled to the first input;
a seventh transistor, having a conduction path coupled between the first power supply terminal and the control terminal of the first output transistor, and a control terminal coupled to the first plate of the third capacitor;
a fourth capacitor, having a first plate, and having a second plate coupled to the second input; and
an eighth transistor, having a conduction path coupled between the first power supply terminal and the control terminal of the second output transistor, and a control terminal coupled to the first plate of the fourth capacitor.

21. The circuit of claim 16, wherein the first and second transistors are in saturation during at least part of signal transition.
